(19) United States
(12) Patent Application Publication
(10) Pub. No.: US 2011/0306181 A1
(43) Pub. Date: Dec. 15, 2011

(54) METHOD OF MANUFACTURING SILICON CARBIDE SUBSTRATE

(75) Inventors: Makoto Sasaki, Hyogo (JP); Shin Harada, Osaka (JP); Taro Nishiguchi, Hyogo (JP); Kyoko Okita, Hyogo (JP); Hiroki Inoue, Hyogo (JP); Yasuo Namikawa, Hyogo (JP)

(73) Assignee: SUMITOMO ELECTRIC INDUSTRIES ,LTD., Osaka-shi ,Osaka (JP)

(21) Appl. No.: 13/202,437

(22) PCT Filed: Sep. 28, 2010
(86) PCT No.: PCT/JP2010/066754

§ 371 Date: Aug. 19, 2011

(30) Foreign Application Priority Data
Jan. 26, 2010 (JP) 2010-014242

(51) Int. Cl. H01L 21/762

(52) U.S. Cl. 438/459; 257/E21.567

(57) ABSTRACT

A method of manufacturing a silicon carbide substrate includes the steps of: preparing a base substrate formed of silicon carbide and a SiC substrate formed of single crystal silicon carbide; fabricating a stacked substrate by stacking the base substrate and the SiC substrate to have their main surfaces in contact with each other; heating the stacked substrate to join the base substrate and the SiC substrate and thereby fabricating a joined substrate; and heating the joined substrate such that a temperature difference is formed between the base substrate and the SiC substrate, and thereby discharging voids formed at the step of fabricating the joined substrate at an interface between the base substrate and the SiC substrate to the outside.

### TECHNICAL FIELD

The present invention relates to a method of manufacturing a silicon carbide substrate and, more specifically, to a method of manufacturing a silicon carbide substrate that can reduce manufacturing cost of a semiconductor device using the silicon carbide substrate.

### BACKGROUND ART

Recently, in order to improve breakdown voltage, decrease loss and to enable use in a high-temperature environment of semiconductor devices, use of silicon carbide (SiC) has become increasingly popular as material for forming semiconductor devices. Silicon carbide is a wide bandgap semiconductor having wider bandgap than silicon that has been widely used as material for forming semiconductor devices. Therefore, if silicon carbide is used as the material for forming semiconductor devices, it becomes possible to improve breakdown voltage and decrease on-resistance of the semiconductor devices. Further, semiconductor devices using silicon carbide as the material are advantageous in that their properties do not much degrade in high-temperature environment as compared with semiconductor devices using silicon as the material.

Under the circumstances, various studies have been made regarding the method of manufacturing silicon carbide crystals and silicon carbide substrates used for manufacturing semiconductor devices, and various ideas have been proposed (for example, see M. Nakabayashi, et al., “Growth of Crack-free 100 mm-diameter 4H—SiC Crystals with Low Micropipe Densities”, Mater. Sci. Forum, vols. 600-603, 2009, pp. 3-6 (Non-Patent Literature 1)).

### CITATION LIST

### Non Patent Literature

NPL 1: M. Nakabayashi, et al., “Growth of Crack-free 100 mm-diameter 4H—SiC Crystals with Low Micropipe Densities”, Mater. Sci. Forum, vols. 600-603, 2009, pp. 3-6

### SUMMARY OF INVENTION

### Technical Problem

Silicon carbide, however, does not have liquid phase under normal pressure. Further, its crystal growth temperature is 2000° C. or higher, which is very high, so that growth conditions control and stabilization are difficult. Accordingly, it is difficult to attain larger diameter of silicon carbide single crystal while maintaining high quality and, hence, it is difficult to obtain a silicon carbide substrate having large diameter and high quality. Because of the difficulty in fabricating silicon carbide substrates of large diameter, manufacturing cost of silicon carbide substrates increases and, in addition, when semiconductor devices are formed using the silicon carbide substrates, the number of devices produced per one batch becomes smaller. Thus, the cost for manufacturing semiconductor devices becomes higher. If the silicon carbide single crystals of which manufacturing cost is high can be used effectively as substrates, the cost for manufacturing semiconductor devices is believed to be decreased.

Therefore, an object of the present invention is to provide a method of manufacturing a silicon carbide substrate that can reduce manufacturing cost of semiconductor devices using silicon carbide substrates.

### Solution to Problem

The present invention provides a method of manufacturing a silicon carbide substrate, including the steps of: preparing a base substrate formed of silicon carbide and a SiC substrate formed of single crystal silicon carbide; fabricating a stacked substrate by stacking the base substrate and the SiC substrate to have their main surfaces in contact with each other; heating the stacked substrate to join the base substrate and the SiC substrate and thereby fabricating a joined substrate; and heating the joined substrate such that a temperature difference is formed between the base substrate and the SiC substrate, and thereby discharging voids formed at the step of fabricating the joined substrate at an interface between the base substrate and the SiC substrate to the outside.

As described above, it is difficult to attain large diameter of silicon carbide single crystal with high quality. On the other hand, in order to realize highly efficient manufacturing in the process for manufacturing semiconductor devices using the silicon carbide substrates, substrates uniformly having prescribed shape and size are necessary. Even if a high-quality silicon carbide single crystal can be obtained, a region that cannot be processed to a prescribed shape by, for example, cutting may not be effectively utilized.

In this regard, according to the method of manufacturing a silicon carbide substrate of the present invention, a SiC substrate formed of single crystal silicon substrate is joined to be in contact with the main surface of a base substrate formed of silicon carbide. Therefore, it is possible, for example, to process the base substrate formed of silicon carbide crystal of low quality to the afore-mentioned prescribed shape and size, and to arrange the silicon carbide single crystal having high quality but not in desirable shape as a SiC substrate on the base substrate. The silicon carbide substrates obtained in this manner uniformly have prescribed shape and size and, therefore, efficiency in manufacturing semiconductor devices can be improved. Further, since the silicon carbide substrate obtained in this manner allows manufacturing of semiconductor devices using SiC substrate of high quality, the silicon carbide single crystal can be used effectively.

As described above, the method of manufacturing a silicon carbide substrate in accordance with the present invention provides a method of manufacturing a silicon carbide substrate that can reduce the cost of manufacturing semiconductor devices using silicon carbide substrates.

Further, when a joined substrate is fabricated by joining a SiC substrate and a base substrate, voids are possibly formed at the interface between the base substrate and the SiC substrate because of warpage and the like of the base substrate and the SiC substrate. If Such a joined substrate having voids therein is used as it is as the silicon carbide substrate for manufacturing semiconductor devices, the voids act as resistance components, whereby resistivity of the substrate increases. This may possibly lead to a problem that on-resistance of the manufactured semiconductor devices increases. Further, if such a joined substrate having voids therein is used as it is as the silicon carbide substrate, presence of the voids decreases strength of the substrate, and the substrate tends to be cracked when handled. In this regard, the method of manufacturing a silicon carbide substrate in accordance with the present invention includes, after the joined substrate is formed by joining the SiC substrate and the base substrate, the step of discharging voids formed at the interface between the base substrate and the SiC substrate at the step of fabricating the joined substrate, by heating the joined substrate such that temperature difference is generated between the base substrate and the SiC substrate. As a result, voids in the silicon carbide substrate are reduced, and above-described problems caused by the existence of voids can be prevented.

The method of manufacturing a silicon carbide substrate described above may further include the step of planarizing a main surface of that one of the base substrate and the SiC substrate which is heated to a higher temperature than the other substrate at the step of discharging the voids to the outside, the main surface being opposite to the other substrate.

The voids in the joined substrate are moved to the side of that one of base substrate and SiC substrate which is heated to a higher temperature and discharged to the outside, at the step of discharging the voids to the outside. Therefore, the main surface of the side heated to the higher temperature has its degree of flatness lowered, because of voids discharged therefrom. In this regard, since the step of planarizing the main surface is provided, the degree of flatness of the main surface, which has been degraded, can be improved to a desired level. Here, the planarization may be realized by polishing the main surface.

In the method of manufacturing a silicon carbide substrate described above, at the step of discharging the voids to the outside, the joined substrate is heated such that temperature of the base substrate becomes higher than the temperature of the SiC substrate.

As a result, the voids are discharged from the side of base substrate. Therefore, the degradation of flatness caused by the discharge of voids of the main surface on the side of SiC substrate, on which an epitaxially grown layer is formed and/or active regions are formed by introducing impurity in manufacturing semiconductor devices, can be prevented.

In the method of manufacturing a silicon carbide substrate described above, at the step of discharging the voids to the outside, a main surface of the base substrate opposite to the SiC substrate may be heated to a temperature range of at least 1500° C. and at most 3000° C.

Since the heating temperature is set to 1500° C. or higher, the speed of movement of voids increases, and the voids can be discharged efficiently. On the other hand, since the heating temperature is set to at most 3000° C., defects such as etching of SiC substrate can be prevented.

In the method of manufacturing a silicon carbide substrate described above, at the step of preparing the base substrate and the SiC substrate, a plurality of SiC substrates are prepared; and at the step of fabricating the stacked substrate, the base substrate and the SiC substrates may be stacked to have their main surfaces in contact with each other, with the plurality of the SiC substrates arranged side by side when viewed two-dimensionally.

As described above, it is difficult to realize high quality silicon carbide single crystal with large diameter. In contrast, by arranging the plurality of SiC substrates obtained from high-quality silicon carbide single crystals aligned side by side when viewed two-dimensionally and by joining the base substrate and the SiC substrates stacked and joined with their main surfaces in contact with each other, a silicon carbide substrate that can be treated as a substrate of large diameter having high quality SiC layer can be obtained. Using the silicon carbide substrate, efficiency of the process for manufacturing semiconductor devices can be improved. In order to improve the efficiency of semiconductor device manufacturing process, it is preferred that the SiC substrates placed next to each other are arranged in contact with each other, among the plurality of SiC substrates. More specifically, it is preferred that the plurality of SiC substrates are laid edge-to-edge in a matrix when viewed two-dimensionally.

In the method of manufacturing a silicon carbide substrate described above, at the step of fabricating the stacked substrate, the stacked substrate may be fabricated such that an off angle of a main surface of the SiC substrate opposite to the base substrate with respect to the {0001} plane becomes at least 50° and at most 65°.

High-quality single crystal can be fabricated efficiently by growth in <0001>direction of hexagonal single crystal silicon carbide. From the silicon carbide single crystal grown in the <0001> direction, silicon carbide substrate having the {0001} plane can be taken with high efficiency. It is possible in some cases to manufacture semiconductor devices of high performance by using a silicon carbide substrate having a main surface of which off angle from the plane orientation of {0001} is at least 50° and at most 65°.

Specifically, a silicon carbide substrate used for fabricating an MOSFET (Metal Oxide Semiconductor Filed Effect Transistor) typically has a main surface whose off angle from the plane orientation of {0001} is about 8°. An epitaxially grown layer is formed on the main surface, and on the epitaxially grown layer, an oxide film, electrodes and the like are formed, whereby the MOSFET is obtained. In the MOSFET, a channel region is formed at a region including an interface between the epitaxially grown layer and the oxide film. In the MOSFET having such a structure, because of the off angle of the main surface of the substrate being about 8° from the {0001} plane, large number of interface states are formed in the vicinity of interface between the epitaxially grown layer and the oxide film where the channel region is formed, resulting in hindering movement of carriers and decreasing channel mobility.

In this connection, at the step of forming the stacked substrate, by forming the stacked substrate such that the off angle of the main surface of SiC substrate opposite to the base substrate with respect to the {0001} plane becomes at least 50° and at most 65°, the off angle of the main surface of the eventually manufactured silicon carbide substrate with respect to the {0001} plane becomes at least 50° and at most 65°, whereby formation of interface states can be reduced and, hence, an MOSFET with lower on-resistance can be produced.

In the method of manufacturing a silicon carbide substrate described above, at the step of fabricating the stacked substrate, the stacked substrate may be fabricated such that an angle formed by an off orientation of the main surface of the SiC substrate opposite to the base substrate and the <1-100> direction becomes at most 5°.

The <1-100> direction is a representative off orientation of a silicon carbide substrate. When the variation in off orientation caused by the variation of slice process and the like at the steps of manufacturing the substrates is made 5° or smaller, it becomes easier to form an epitaxially grown layer on the silicon carbide substrate.

In the method of manufacturing a silicon carbide substrate described above, at the step of fabricating the stacked substrate, the stacked substrate may be fabricated such that an off angle of the main surface of the SiC substrate opposite to the base substrate with respect to the {03-38} plane in the <1-100> direction becomes at least 3° and at most 5°.

By this approach, channel mobility when the MOSFET is formed by using the silicon carbide substrate can further be improved. Here, the off angle from the plane orientation of {03-38} is set to be at least −3° and at most +5°, since particularly high channel mobility could be observed in this range when the relation between the channel mobility and the off angle was studied.

Further, the “off angle with respect to the {03-38} plane in the <1-100> direction” refers to an angle formed by the orthogonal projection of the normal of said main surface to the flat plane defined by the <1-100> and <0001> directions and the normal of the {03-38} plane, and its sign is positive if the orthogonal projection comes in parallel and closer to the <1-100> direction and negative if the orthogonal projection comes in parallel and closer to the <0001> direction.

Preferably, the plane orientation of the main surface is substantially {03-38} and more preferably, the plane orientation of the main surface is {03-38}. Here, that the plane orientation of the main surface is substantially {03-38} means that the plane orientation of the substrate main surface is in the off angle range of which plane orientation can substantially be regarded as {03-38} considering processing accuracy and the like, and the off angle range here is the off angle of ±2° from {03-38}. With this configuration, the channel mobility mentioned above can further be improved.

In the method of manufacturing a silicon carbide substrate described above, at the step of fabricating the stacked substrate, the stacked substrate may be fabricated such that an angle formed by an off orientation of the main surface of the SiC substrate opposite to the base substrate and the <11-20> direction becomes at most 5°.

The <11-20> direction is, as is the <1-100> direction mentioned above, a representative off orientation of a silicon carbide substrate. When the variation in off orientation caused by the variation of slice process and the like at the steps of manufacturing the substrates is made ±5°, it becomes easier to form an epitaxially grown layer on the SiC substrate.

The method of manufacturing a silicon carbide substrate described above may further include the step of polishing a main surface of the SiC substrate corresponding to the main surface of the SiC substrate opposite to the base substrate.

By this approach, it becomes possible to form an epitaxially grown layer with high quality on the main surface of SiC substrate opposite to the base substrate. As a result, it becomes possible to manufacture a semiconductor device including the epitaxially grown layer with high quality as, for example, an active layer. Specifically, by adopting such a process step, it becomes possible to obtain a silicon carbide substrate allowing manufacturing of high quality semiconductor devices, including the epitaxially grown layer formed on the SiC substrate. Here, the main surface of the SiC substrate may be polished after the base substrate and the SiC substrate are joined, or the main surface of SiC substrate to be the main surface opposite to the side of base substrate may be polished in advance, before the base substrate and the SiC substrate are joined.

In the method of manufacturing a silicon carbide substrate described above, the step of fabricating the joined substrate may be executed without polishing the main surfaces of the base substrate and the SiC substrate to face each other at the step of fabricating the joined substrate, before the step of fabricating the joined substrate.

By this approach, the cost of manufacturing the silicon carbide substrate can be reduced. Here, the main surfaces of base substrate and SiC substrate to be facing each other at the step of forming the joined substrate may not be polished as described above.

However, from the viewpoint of removing a damaged layer near the surface resulting, for example, from slicing at the time of forming the substrate, it is preferred that the step of forming the joined substrate is executed after removing the damaged layer by, for example, etching.

In the method of manufacturing a silicon carbide substrate described above, at the step of fabricating the joined substrate, the stacked substrate may be heated under a pressure higher than 10⁻¹ Pa and lower than 10⁴ Pa. By this approach, it becomes possible to join by a simple apparatus, and the atmosphere for joining can be obtained in a relatively short period of time. Thus, the cost of manufacturing the silicon carbide substrate can be reduced.

### Advantageous Effects of Invention

As is clearly understood from the foregoing description, the method of manufacturing a silicon carbide substrate of the present invention provides a method of manufacturing a silicon carbide substrate that can reduce the cost of manufacturing semiconductor devices using the silicon carbide substrates.

### BRIEF DESCRIPTION OF DRAWINGS

FIG. 1 is a flowchart schematically representing the method of manufacturing a silicon carbide substrate in accordance with Embodiment 1.

FIG. 2 is a schematic cross-sectional view illustrating the method of manufacturing a silicon carbide substrate in accordance with Embodiment 1.

FIG. 3 is a schematic cross-sectional view illustrating the method of manufacturing a silicon carbide substrate in accordance with Embodiment 1.

FIG. 4 is a schematic partial cross-sectional view showing, in enlargement, a portion around a void shown in FIG. 3.

FIG. 5 is a schematic cross-sectional view illustrating the method of manufacturing a silicon carbide substrate in accordance with Embodiment 1.

FIG. 6 is a schematic cross-sectional view showing a structure of the silicon carbide substrate in accordance with Embodiment 1.

FIG. 7 is a schematic cross-sectional view showing a structure of the silicon carbide substrate in accordance with Embodiment 1.

FIG. 8 is a schematic cross-sectional view illustrating the method of manufacturing a silicon carbide substrate in accordance with Embodiment 2.

FIG. 9 is a schematic cross-sectional view illustrating the method of manufacturing a silicon carbide substrate in accordance with Embodiment 2.

FIG. 10 is a schematic cross-sectional view showing a structure of the silicon carbide substrate in accordance with Embodiment 2.

FIG. 11 is a schematic cross-sectional view showing a structure of the silicon carbide substrate in accordance with Embodiment 2.

FIG. 12 is a schematic cross-sectional view showing a structure of a vertical MOSFET.

FIG. 13 is a flowchart schematically representing the method of manufacturing the vertical MOSFET.

FIG. 14 is a schematic cross-sectional view illustrating the method of manufacturing the vertical MOSFET.

FIG. 15 is a schematic cross-sectional view illustrating the method of manufacturing the vertical MOSFET.

FIG. 16 is a schematic cross-sectional view illustrating the method of manufacturing the vertical MOSFET.

FIG. 17 is a schematic cross-sectional view illustrating the method of manufacturing the vertical MOSFET.

### DESCRIPTION OF EMBODIMENTS

In the following, embodiments of the present invention will be described with reference to the figures. In the following description, the same or corresponding portions are denoted by the same reference characters, and description thereof will not be repeated.

### Embodiment 1

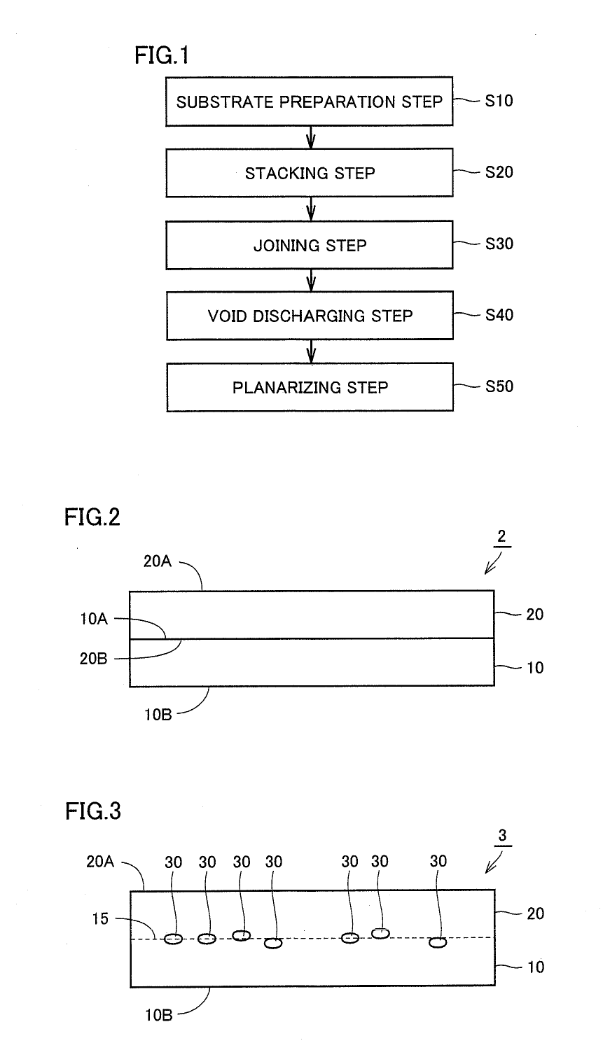

First, referring to FIGS. 1 to 7, Embodiment 1 as an embodiment of the present invention will be described. Referring to FIG. 1, in the method of manufacturing a silicon carbide substrate in accordance with the present embodiment, first, the substrate preparation step is executed as step (S10). Referring to FIG. 2, at this step (S10), by way of example, a base substrate 10 formed of single crystal silicon carbide and a SiC substrate 20 formed of a single crystal silicon carbide are prepared.

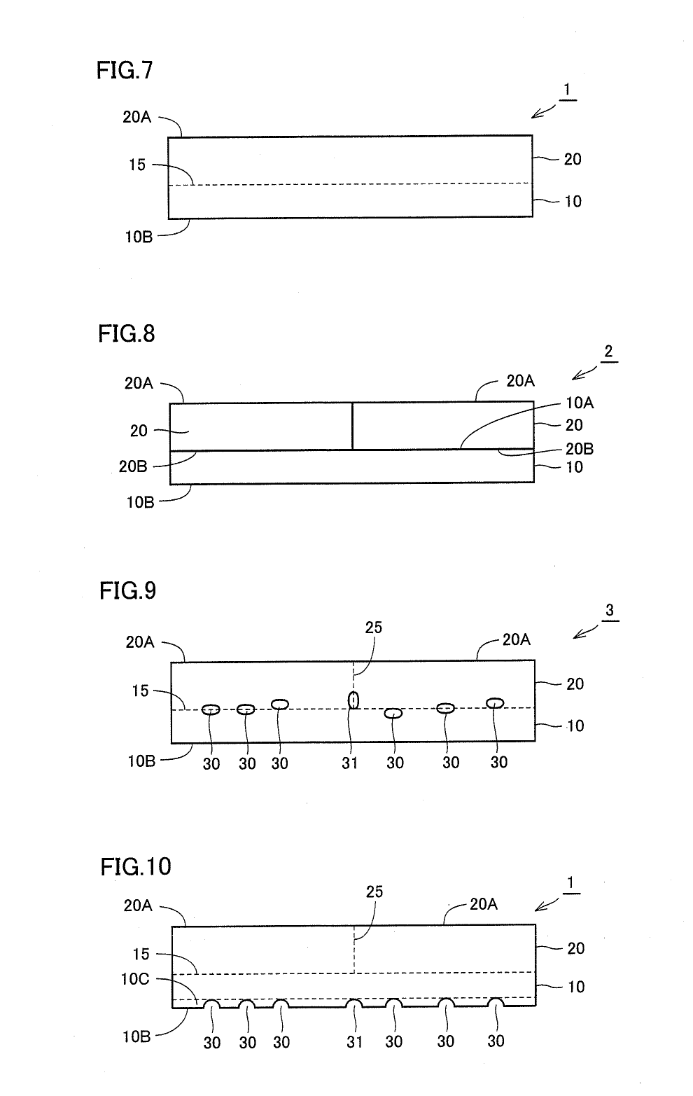

Here, since a main surface 20A of SiC substrate 20 will be the main surface of silicon carbide substrate obtained by the manufacturing method (see FIGS. 6 and 7 as will be described later), the plane orientation of main surface 20A of SiC substrate 20 is selected in accordance with the desired plane orientation of the main surface. By way of example, here, SiC substrate 20 having the main surface of {03-38} plane is prepared. As base substrate 10, for example, a substrate having impurity density higher than 2×10¹⁹ cm⁻³ may be adopted. As SiC substrate 20, a substrate having the impurity density higher than 5×10¹⁸ cm⁻³ and lower than 2×10¹⁹ cm⁻³ may be adopted. Base substrate 10 is not limited to one formed of single crystal, and a base formed of polycrystalline, amorphous or sintered body may be used.

Thereafter, the stacking step is executed as step (S20). Referring to FIG. 2, at this step (S20), base substrate 10 and SiC substrate 20 are stacked to have their main surfaces 10A and 20B in contact with each other, whereby a stacked substrate 2 is formed.

Thereafter, the joining step is executed as step (S30). At this step (S30), the stacked substrate 2 mentioned above is heated, whereby base substrate 10 and SiC substrate 20 are joined. By this step, a joined substrate 3 is obtained, as can be seen from FIG. 3. At this step (S30), stacked substrate 2 mentioned above may be heated under a pressure higher than 10⁻¹ Pa and lower than 10⁴ Pa. By this approach, it becomes possible to join by a simple apparatus, and the atmosphere for joining can be obtained in a relatively short period of time. Thus, the cost of manufacturing silicon carbide substrate 10 can be reduced. The atmosphere at the time of heating at step (S30) may be an inert gas atmosphere. If the inert gas atmosphere is adopted as the atmosphere, it is preferred that the atmosphere is an inert gas atmosphere containing at least one selected from the group consisting of argon, helium and nitrogen. Alternatively, at this step (S30), stacked substrate 20 may be heated in an atmosphere obtained by reducing the atmospheric pressure. By such an approach, the cost of manufacturing silicon carbide substrate 10 can be reduced.

It is noted that as base substrate 10 and SiC substrate 20 prepared at step (S10), it is difficult to prepare a substrate having perfectly flat shape without any warpage or other deformation. Therefore, in stacked substrate 2 formed at step (S20), base substrate 10 and SiC substrate 20 are not fully in tight contact with each other over the entire surfaces, and in most cases, there are regions in contact with each other and regions not in contact with each other. As a result, at step (S30), voids 30 are formed in the vicinity of the joint interface 15 between base substrate 10 and SiC substrate 20.

Next, the void discharging step is executed as step (S40). At this step (S40), joined substrate 30 is heated such that temperature difference is generated between base substrate 10 and SiC substrate 20. Specifically, joined substrate 3 is heated such that the temperature of base substrate 10 becomes higher than the temperature of SiC substrate 20.

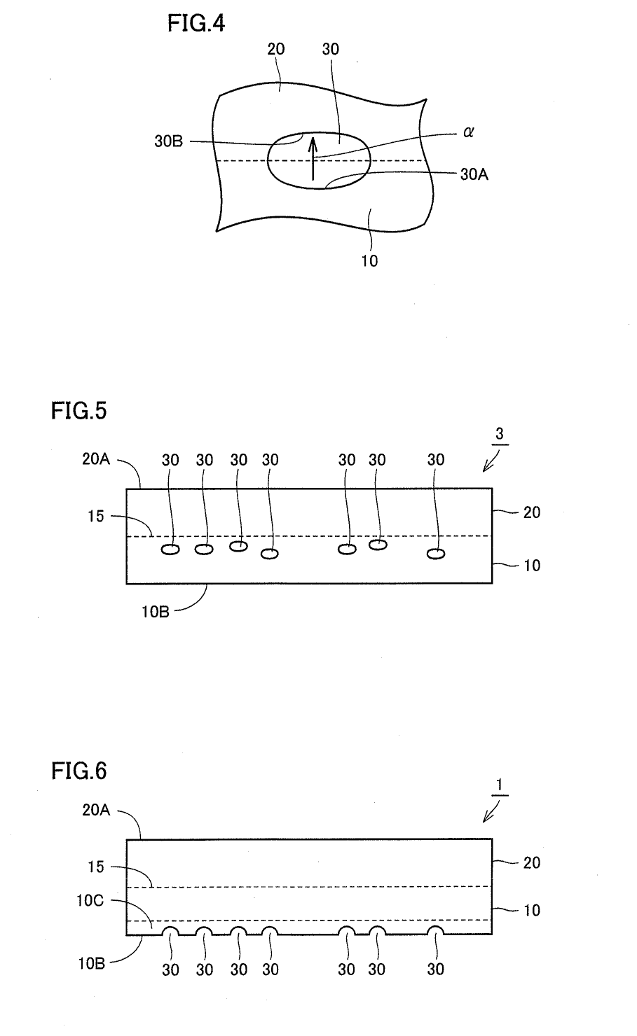

Referring to FIG. 4, here, in void 30, silicon carbide forming a region along an inner wall 30A of base substrate 10 at the higher temperature moves along an arrow α because of sublimation, and thereafter reaches an inner wall 30B on the side of SiC substrate 20 at the lower temperature and is solidified. Consequently, void 30 moves to the side of base substrate 10, as shown in FIG. 5. By maintaining such a state, voids 30 reach the main surface 10B of base substrate 10 opposite to SiC substrate 20 and discharged to the outside, as shown in FIG. 6. The time necessary for discharging voids 30 changes depending on the thickness of the substrate, speed of movement of voids and the like. By way of example, assuming that the thickness of base substrate 10 is 500μm, the time is at least 1 hour and at most 48 hours. By the above-described steps, silicon carbide substrate in accordance with the present embodiment shown in FIG. 6 is completed. Here, heating may be done to cause the temperature of either base substrate 10 or SiC substrate 20 to be higher. In the present embodiment, however, from the viewpoint of reducing influence of voids 30 on the quality of SiC substrate 20, joined substrate 30 is heated such that the temperature on the side of base substrate 10 becomes higher than the temperature on the side of SiC substrate 20, in order to move voids 30 to the side of base substrate 10. Heating of joined substrate 30 may be executed on a susceptor or a crucible formed of graphite, or formed of graphite and having its surface coated with tantalum carbide. It is noted that the speed of movement of voids 30 becomes higher if the ambient pressure is lower. Therefore, in view of improving production efficiency, it is desirable to reduce the ambient pressure, and specifically, the pressure should preferably be made lower than the atmospheric pressure. At the time of heating, rare gas (such as argon) or nitrogen may be used as the atmosphere.

According to the process described above, it is possible to provide silicon carbide substrate 1 of desired shape and size by selecting, for example, the shape of base substrate 10, and this leads to improved efficiency of manufacturing semiconductor devices. Further, by the silicon carbide substrate 1 manufactured by the process, it becomes possible to manufacture semiconductor devices using SiC substrate 20 of high-quality silicon carbide single crystal, which has not been used in the past because of difficulty of processing to a desired shape. Therefore, the silicon carbide single crystal can be utilized effectively. As a result, by the method of manufacturing silicon carbide substrate 1 in accordance with the present embodiment, silicon carbide substrate 1 that allows reduction of the cost of manufacturing semiconductor devices using the silicon carbide substrate can be manufactured.

Further, by the above-described process, voids 30 formed in the vicinity of joint interface 15 between base substrate 10 and SiC substrate 20 are discharged to the outside at step (S40). Therefore, the number of voids 30 in silicon carbide substrate 1 can be reduced and, as a result, increase of substrate resistance, decrease of substrate strength and the like caused by the presence of voids 30 can be prevented.

Further, in the present embodiment, the planarizing step is executed as step (S50). At this step (S50), main surface 10B of base substrate 10 opposite to SiC substrate 20, heated to a temperature higher than SiC substrate 20, is planarized by, for example, polishing. Specifically, referring to FIG. 6, a surface layer region 10C including main surface 10B having ups and downs generated by the discharge of voids 30 left thereon is removed by polishing. Though this step (S50) in not an essential step, this step provides silicon carbide substrate 1 with main surface 10B on the side of discharging voids 30 of base substrate 10 reliably made flat.

Here, at step (S40), preferably, the main surface 10B of base substrate 10 opposite to SiC substrate 20 is heated to a temperature range of 1500° C. to 3000° C. When the heating temperature is set to 1500° C. or higher, the speed of movement of voids 30 increases, and voids 30 can be discharged with high efficiency. On the other hand, when the heating temperature is set to 3000° C. or lower, damage to SiC substrate 20 such as etching can be prevented.

Further, main surface 20A of SiC substrate 20 may have the off angle from the {0001} plane of at least 50° and at most 65°. With such an angle, when a MOSFET is fabricated using the thus manufactured silicon carbide substrate 1, an MOSFET having formation of interface states reduced and hence on-resistance lowered can be obtained. On the other hand, considering the ease of manufacturing, main surface 20A of SiC substrate may be of the {0001} plane.

Further, the angle formed by the off orientation of main surface 20A of SiC substrate 20 and the <1-100> direction may be 5° or smaller. The <1-100> direction is a typical off orientation of a silicon carbide substrate. When the variation in off orientation caused by the variation of slice process and the like at the steps of manufacturing the substrates is made 5° or smaller, it becomes easier to form an epitaxially grown layer on silicon carbide substrate 10 (on main surface 20A).

Further, preferably, the off angle of main surface 20A of SiC substrate 20 with respect to the {03-38} plane in the <1-100> direction is set to at least −3° and at most 5°. With such an angle, channel mobility in the MOSFET foamed using the thus manufactured silicon carbide substrate 1 can further be improved. On the other hand, an angle formed by the off orientation of main surface 20A of SiC substrate 20 and the <11-20> direction may be 5° or smaller.

The <11-20> direction is also a typical off orientation of the silicon carbide substrate. When the variation in off orientation caused by the variation of slice process and the like at the steps of manufacturing the substrates is made ±5°, it becomes easier to form an epitaxially grown layer on silicon carbide substrate 1 (on main surface 20A).

Further, the method of manufacturing silicon carbide substrate 1 in accordance with the present embodiment may further include the step of polishing the main surface of SiC substrate 20 that corresponds to main surface 20A of SiC substrate 20 opposite to base substrate 10, of the stacked substrate. This enables formation of an epitaxially grown layer of high quality on main surface 20A. As a result, a semiconductor device including the epitaxial layer of high quality as an active layer, for example, can be manufactured. Specifically, by adopting such a step, silicon carbide substrate 1 allowing manufacturing of a high-quality semiconductor device including an epitaxially grown layer formed on SiC substrate 20 can be obtained. The step of polishing may be executed before or after joining base substrate 10 and SiC substrate 20, provided that the step is executed after step (S10).

Further, in the method of manufacturing silicon carbide substrate 1 in accordance with the present embodiment, the process (S30) may be executed without polishing the main surfaces of base substrate 10 and SiC substrate 20, which are to be facing each other. This reduces the cost of manufacturing silicon carbide substrate 1. Further, from the viewpoint of removing a damaged layer close to the surface formed by slicing, the step of removing the damaged layer by, for example, etching may be executed, followed by step (S30).

### Embodiment 2

Next, Embodiment 2 as another embodiment of the present invention will be described. The method of manufacturing a silicon carbide substrate in accordance with Embodiment 2 is executed basically in the same manner as in Embodiment 1. However, the method of manufacturing a silicon carbide substrate in accordance with Embodiment 2 differs in the arrangement of SiC substrate from the method of Embodiment 1.

Referring to FIG. 1, in the method of manufacturing a silicon carbide substrate in accordance with Embodiment 2, as in Embodiment 1, first, the substrate preparation step is executed as step (S10). At this step (S10), base substrate 10 and SiC substrate 20 are prepared. Here, in the present embodiment, a plurality of SiC substrates 20 are prepared.

Next, the stacking step is executed as step (S20). Referring to FIG. 8, at this step (S20), the plurality of SiC substrates prepared at step (S10) are arranged, aligned side by side when viewed two-dimensionally, in contact with main surface 10A of base substrate 10. Specifically, a plurality of SiC substrates 20 are arranged along main surface 10A of base substrate 10. Here, the plurality of SiC substrates 20 may be arranged in a matrix with neighboring SiC substrates 20 being in contact with each other, on base substrate 10. Alternatively, SiC substrates 20 may be arranged spaced apart from each other. Then, the space is preferably at most 100 μm and more preferably at most 10 μm.

As in Embodiment 1, the joining step is executed as step (S30), and joined substrate 3 is obtained (see FIG. 9). Here, as in Embodiment 1, voids 30 are formed in the vicinity of joint interface 15 between base substrate 10 and SiC substrate 20. Further, in the present embodiment, voids 31 are formed also in the vicinity of joint interface 25 between each of SiC substrates 20.

Next, as in Embodiment 1, the void discharging step is executed as step (S40). Thus, voids 30 formed in the vicinity of joint interface 15 reach main surface 10B of base substrate 10 opposite to SiC substrate 20, and are discharged to the outside. Further, voids 31 formed in the vicinity of joint interface 25 between each of SiC substrates 20 similarly reach main surface 10B and are discharged to the outside. By the procedure described above, silicon carbide substrate 1 shown in FIG. 10 is completed. Since a plurality of SiC substrates 20 are used in silicon carbide substrate 1, it is easier to realize larger diameter and, as a result, the cost of manufacturing semiconductor devices using the silicon carbide substrate can further be reduced.

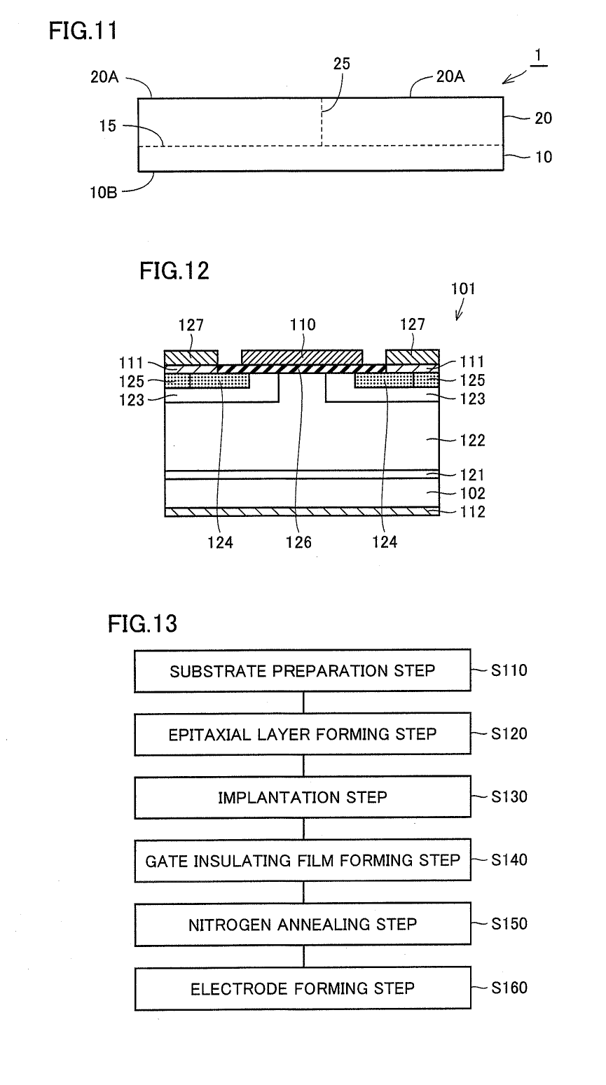

Referring to FIGS. 10 and 11, as in Embodiment 1, the step (S50) is further executed, whereby the surface area region 10C including main surface 10B, with remaining ups and downs resulting from discharge of voids 30 and 31 of base substrate 10, is removed by polishing. Thus, referring to FIG. 11, silicon carbide substrate 1 with main surface 10B on the side of discharging voids 30 and 31 of base substrate 10 reliably made flat can be obtained.

### Embodiment 3

Next, an example of a semiconductor device formed by using the silicon carbide substrate manufactured in accordance with the method of manufacturing a silicon carbide substrate of the present invention as above will be described as Embodiment 3. Referring to FIG. 12, a semiconductor device 101 in accordance with the present embodiment is a vertical DiMOSFET (Double Implanted Metal Oxide Semiconductor Field Effect Transistor), having a substrate 102, a buffer layer 121, a breakdown voltage holding layer 122, a p-region 123, an n⁺ region 124, a p⁺ region 125, an oxide film 126, a source electrode 111, an upper source electrode 127, a gate electrode 110 and a drain electrode 112 formed on the side of backside surface of substrate 102. Specifically, on a surface of substrate 102 formed of silicon carbide of n-type conductivity, buffer layer 121 of silicon carbide is formed. As substrate 102, a silicon carbide substrate manufactured by the method of manufacturing a silicon carbide substrate of the present invention, including silicon carbide substrate 1 described in Embodiments 1 and 2, is adopted. If silicon carbide substrate 1 in accordance with Embodiment 1 or 2 is adopted, buffer layer 121 is formed on SiC substrate 20 of silicon carbide substrate 1. Buffer layer 121 has n-type conductivity, and its thickness is, for example, 0.5 μm. The density of n-type conductive impurity in buffer layer 121 is, for example, 5×10¹⁷ cm⁻³. Breakdown voltage holding layer 122 is formed on buffer layer 121. Breakdown voltage holding layer 122 is formed of silicon carbide having n-type conductivity, and its thickness is, for example, 10 μm. The density of n-type conductive impurity in breakdown voltage holding layer 122 may be 5×10¹⁵ cm⁻³.

On a surface of breakdown voltage holding layer 122, p-regions 123 having p-type conductivity are formed spaced apart from each other. In p-region 123, an n⁺ region 124 is formed at a surface layer of p-region 123. A p⁺ region 125 is formed at a position next to n⁺ region 124. Extending from above n⁺ region 124 on one p-region 123 over breakdown voltage holding layer 122 exposed between two p-regions 123, the other p-region 123 and above n⁺ region 124 in the said the other p-region 123, oxide film 126 is formed. On oxide film 126, gate electrode 110 is formed. Further, on n⁺ region 124 and p⁺ region 125, source electrode 111 is formed. On source electrode 111, an upper source electrode 127 is formed. At the backside surface of substrate 102, that is, the surface opposite to the side where buffer layer 121 is formed, drain electrode 112 is formed.

In semiconductor device 101 in accordance with the present embodiment, the silicon carbide substrate in accordance with the present invention such as silicon carbide substrate 1 described in Embodiments 1 and 2 is used as substrate 102. Here, the silicon carbide substrate in accordance with the present invention is manufactured by the method of manufacturing a silicon carbide substrate that can reduce the cost of manufacturing semiconductor devices using the silicon carbide substrate and that attains lower resistivity and higher strength. Therefore, semiconductor device 101 is a device of which manufacturing cost is reduced and which has reduced on-resistance.

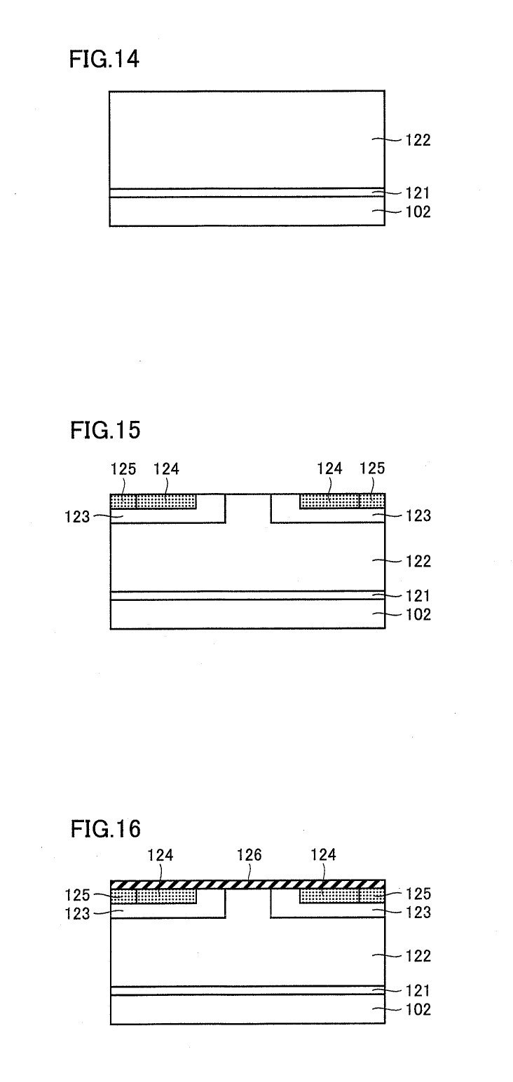

Next, the method of manufacturing semiconductor device 101 shown in FIG. 12 will be described with reference to FIGS. 13 to 17. Referring to FIG. 13, first, the substrate preparation step (S110) is executed. Here, substrate 102 (see FIG. 14) having the {03-38} plane as the main surface, for example, is prepared. As substrate 102, silicon carbide substrate 1 of the present invention described above, including silicon carbide substrate 1 manufactured by the method described in Embodiment 1 or 2, is prepared.

As substrate 102 (see FIG. 14), a substrate having n-type conductivity and substrate resistance of 0.02 Ωcm may be used.

Next, as shown in FIG. 13, the epitaxial layer forming step (S120) is executed. Specifically, buffer layer 121 is formed on the surface of substrate 102. Buffer layer 121 is formed on a main surface 20A of SiC substrate 20 (see FIGS. 6, 7, 10 and 11) of silicon carbide substrate 1 adopted as substrate 102. Buffer layer 121 is formed of silicon carbide having n-type conductivity and, by way of example, it is formed as an epitaxial layer of 0.5 μm in thickness. The density of conductive impurity in buffer layer 121 may be, for example, 5×10¹⁷ cm⁻³. On buffer layer 121, breakdown voltage holding layer 122 is formed as shown in FIG. 14. As breakdown voltage holding layer 122, a layer of silicon carbide having n-type conductivity is formed by epitaxial growth. The thickness of breakdown voltage holding layer 122 is, for example, 10 μm. Density of n-type conductive impurity in breakdown voltage holding layer 122 is, for example, 5×10¹⁵ cm⁻³.

Next, the implantation step (S130) is executed as shown in FIG. 13. Specifically, using an oxide film formed by photolithography and etching as a mask, impurity of p-type conductivity is introduced to breakdown voltage holding layer 122, whereby p-region 123 is formed as shown in FIG. 15. The oxide film used here is removed, and an oxide film having a new pattern is again formed by photolithography and etching. Using the oxide film as a mask, impurity of n-type conductivity is introduced to a prescribed region, to form n+ region 124. Further, by introducing impurity of p-type conductivity in the same manner, p+ region 125 is formed. As a result, a structure such as shown in FIG. 15 is obtained.

After the implantation process as described above, an activation annealing treatment is done. By way of example, annealing is done under the conditions such as an argon atmosphere, at a heating temperature of 1700° C. for 30 minutes.

Next, as shown in FIG. 13, the gate insulating film forming step (step S140) is executed. Specifically, oxide film 126 is formed to cover breakdown voltage holding layer 122, p-region 123, n⁺ region 124 and p⁺ region 125 as shown in FIG. 16. The film may be formed by dry oxidation (thermal oxidation). Conditions for dry oxidation are, for example, heating temperature of 1200° C. and heating time of 30 minutes.

Thereafter, the nitrogen annealing step (step S150) is done. Specifically, annealing is done using nitrogen monoxide (NO) as atmosphere gas. Temperature conditions for the annealing process are, for example, heating temperature of 1100° C. and heating time of 120 minutes. As a result, nitrogen atoms are introduced to the vicinity of interface between oxide film 126 and each of the lower layers, that is, breakdown voltage holding layer 122, p-region 123, n⁺ region 124 and p⁺ region 125. Following the annealing step using nitrogen monoxide, annealing using argon (Ar) gas as an inert gas may additionally be performed. Specific conditions are, for example, argon gas as the atmosphere gas, heating temperature of 1100° C. and heating time of 60 minutes.

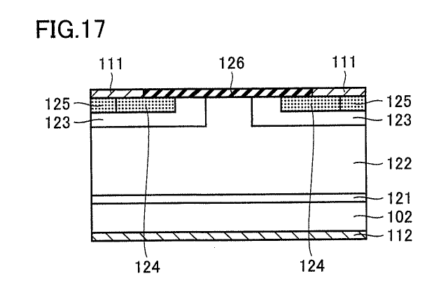

Next, the electrode forming step (step S160) is executed as shown in FIG. 13. Specifically, on oxide film 126, using photolithography, a resist film having a pattern is formed. Using the resist film as a mask, portions of oxide film 126 positioned on n⁺ region 124 and p⁺ region 125 are removed by etching. Thereafter, a conductive film such as metal is formed on the resist film, to be in contact with n⁺ region 124 and p⁺ region 125 in openings formed in oxide film 126. Then, the resist film is removed, and the conductive film that has been positioned on the resist film is removed (lift off). Here, nickel (Ni) may be used as the conductor. As a result, source electrode 111 and drain electrode 112 are obtained as shown in FIG. 17. Here, heat treatment for alloying is preferably carried out. By way of example, heat treatment (alloying process) is done in an atmosphere of argon (Ar) gas as an inert gas, at a heating temperature of 950° C. for 2 minutes.

Thereafter, upper source electrode 127 (see FIG. 12) is formed on source electrode 111. Further, drain electrode 112 (see FIG. 12) is formed on the backside surface of substrate 102. Further, on oxide film 126, gate electrode 110 (see FIG. 12) is formed. In this manner, semiconductor device 101 shown in FIG. 12 is obtained. Specifically, semiconductor device 101 is fabricated by forming an epitaxial layer and electrodes on SiC substrate 20 of silicon carbide substrate 1.

In Embodiment 3 above, a vertical MOSFET has been described as an example of a semiconductor device that can be formed using the silicon carbide substrate manufactured in accordance with the method of manufacturing a silicon carbide substrate of the present invention. Semiconductor devices that can be formed are not limited to the above. Various semiconductor devices including a JEFT (Junction Field Effect Transistor), IGBT (Insulated Gate Bipolar Transistor), and Schottky barrier diode may be formed using the silicon carbide substrate in accordance with the present invention. Further, though an example in which a semiconductor device is fabricated by forming an epitaxial layer functioning as an active layer on the silicon carbide substrate having the {03-38} plane as a main surface has been described, the crystal plane that can be used as the main surface is not limited to this plane, and an arbitrary crystal plane including the (0001) plane may be adopted as the main surface in accordance with the intended use.

As described above, by the method of manufacturing a silicon carbide substrate of the present invention, a silicon carbide substrate that can reduce the cost of manufacturing semiconductor devices can be manufactured. Specifically, the silicon carbide substrate in accordance with the present invention is manufactured by the method of manufacturing the silicon carbide substrate of the present invention as described above. Further, as described with reference to Embodiment 3 above, semiconductor devices can be fabricated using the silicon carbide substrate in accordance with the present invention. Specifically, the semiconductor device in accordance with the present invention has an epitaxially grown layer as an active layer formed on the silicon carbide substrate manufactured in accordance with the method of manufacturing a silicon carbide substrate of the present invention. From a different viewpoint, the semiconductor device in accordance with the present invention has the epitaxially grown layer as an active layer formed on the silicon carbide substrate of the present invention as described above. More specifically, the semiconductor device in accordance with the present invention includes the silicon carbide substrate of the present invention described above, the epitaxially grown layer formed on the silicon carbide substrate, and electrodes formed on the epitaxially grown layer.

The embodiments as have been described here are mere examples and should not be interpreted as restrictive. The scope of the present invention is determined by each of the claims with appropriate consideration of the written description of the embodiments and embraces modifications within the meaning of, and equivalent to, the languages in the claims.

### INDUSTRIAL APPLICABILITY

The method of manufacturing a silicon carbide substrate in accordance with the present invention is advantageously applicable particularly to a method of manufacturing a silicon carbide substrate used for manufacturing semiconductor devices, where improvement in efficiency of manufacturing semiconductor devices is desired.

### REFERENCE SIGNS LIST

1 silicon carbide substrate, 2 stacked substrate, 3 joined substrate, 10 base substrate, 10A, 10B main surfaces, 10C surface layer region, 15 joint interface, 20 SiC substrate, 20A, 20B main surfaces, 25 joint interface, 30, 31 voids, 30A, 30B inner walls, 101 semiconductor device, 102 substrate, 110 gate electrode, 111 source electrode, 112 drain electrode, 121 buffer layer, 122 breakdown voltage holding layer, 123 p-region, 124 n+ region, 125 p+ region, 126 oxide film, 127 upper source electrode.

1. A method of manufacturing a silicon carbide substrate, comprising the steps of:
preparing a base substrate formed of silicon carbide and a SiC substrate formed of single crystal silicon carbide;
fabricating a stacked substrate by stacking said base substrate and said SiC substrate to have their main surfaces in contact with each other;
heating said stacked substrate to join said base substrate and said SiC substrate and thereby fabricating a joined substrate; and
heating said joined substrate such that a temperature difference is formed between said base substrate and said SiC substrate, and thereby discharging voids formed at said step of fabricating said joined substrate at an interface between said base substrate and said SiC substrate to the outside.

2. The method of manufacturing a silicon carbide substrate according to claim 1, further comprising the step of
planarizing a main surface of that one of said base substrate and said SiC substrate which is heated to a higher temperature than the other substrate at the step of discharging said voids to the outside, the main surface being opposite to said the other substrate.

3. The method of manufacturing a silicon carbide substrate according to claim 1, wherein
at said step of discharging said voids to the outside, said joined substrate is heated such that temperature of said base substrate becomes higher than temperature of said SiC substrate.

4. The method of manufacturing a silicon carbide substrate according to claim 3, wherein
at said step of discharging said voids to the outside, a main surface of said base substrate opposite to said SiC substrate is heated to a temperature range of at least 1500° C. and at most 3000° C.

5. The method of manufacturing a silicon carbide substrate according to claim 1, wherein
at said step of preparing said base substrate and said SiC substrate, a plurality of said SiC substrates are prepared; and
at said step of fabricating said stacked substrate, said base substrate and said SiC substrates are stacked to have their main surfaces in contact with each other, with the plurality of said SiC substrates arranged side by side when viewed two-dimensionally.

6. The method of manufacturing a silicon carbide substrate according to claim 1, wherein
at said step of fabricating the stacked substrate, said stacked substrate is fabricated such that an off angle of a main surface of said SiC substrate opposite to said base substrate with respect to the {0001} plane becomes at least 50° and at most 65°.

7. The method of manufacturing a silicon carbide substrate according to claim 6, wherein
at said step of fabricating the stacked substrate, said stacked substrate is fabricated such that an angle formed by an off orientation of the main surface of said SiC substrate opposite to said base substrate and the <1-100> direction becomes at most 5°.

8. The method of manufacturing a silicon carbide substrate according to claim 7, wherein
at said step of fabricating the stacked substrate, said stacked substrate is fabricated such that an off angle of the main surface of said SiC substrate opposite to said base substrate with respect to the {03-38} plane in the <1-100> direction becomes at least −3° and at most 5°.

9. The method of manufacturing a silicon carbide substrate according to claim 6, wherein
at said step of fabricating the stacked substrate, said stacked substrate is fabricated such that an angle formed by an off orientation of the main surface of said SiC substrate opposite to said base substrate and the <11-20> direction becomes at most 5°.

10. The method of manufacturing a silicon carbide substrate according to claim 1, further comprising the step of
polishing a main surface of said SiC substrate corresponding to the main surface of said SiC substrate opposite to said base substrate.

11. The method of manufacturing a silicon carbide substrate according to claim 1, wherein
said step of fabricating said joined substrate is executed without polishing the main surfaces of said base substrate and said SiC substrate to face each other at said step of fabricating said joined substrate, before the step of fabricating said joined substrate.

12. The method of manufacturing a silicon carbide substrate according to claim 1, wherein
at said step of fabricating said joined substrate, said stacked substrate is heated under a pressure higher than 10⁻¹ Pa and lower than 10⁴ Pa.
